(19) United States
(12) Patent Application Publication
(10) Pub. No.: US 2017/0012556 A1
(43) Pub. Date: Jan. 12, 2017

(54) DC-AC POWER CONVERTING CIRCUIT

(71) Applicant: SAMSUNG ELECTRO-MECHANICS CO., LTD., Suwon-si (KR)

(72) Inventors: In Wha JEONG, Suwon-si (KR); Jae Suk SUNG, Suwon-si (KR); Hugh KIM, Suwon-si (KR)

(73) Assignee: SAMSUNG ELECTRO-MECHANICS CO., LTD., Suwon-si (KR)

(21) Appl. No.: 15/016,586

(22) Filed: Feb. 5, 2016

(30) Foreign Application Priority Data
Jul. 9, 2015 (KR) 10-2015-0097838

(51) Int. Cl. H02M 7/5387; H01L 41/107

(52) U.S. Cl. CPC H02M 7/5387; H01L 41/107

(57) ABSTRACT

A direct current (DC)-alternating current (AC) power convertor is disclosed. The DC-AC power converting circuit may include an inverter configured to convert the DC power into first output power, a piezoelectric transforming unit including piezoelectric transformers connected in parallel to an output terminal of the inverter, and each piezoelectric transformer of the piezoelectric transformers configured to transform the first output power to second output power, and an output configured to add the second output power output from the each of the piezoelectric transformer and to output AC power, wherein each piezoelectric transformer has a resonance frequency.

### CROSS-REFERENCE TO RELATED APPLICATION

This application claims the benefit under 35 USC §119(a) of Korean Patent Application No. 10-2015-0097838, filed on Jul. 9, 2015 in the Korean Intellectual Property Office, the entire disclosure of which is incorporated herein by reference for all purposes.

### BACKGROUND

1. Field

The following description relates to a direct current (DC)-alternating current (AC) power converting circuit in which an inverter and a piezoelectric transformer are integrated into a power converting circuit.

2. Description of Related Art

In a power supply technique, a switching frequency is increased to achieve high density and high efficiency. This is because sizes of elements, such as, for example, a transformer may be reduced as a switching frequency is increased. High density leads to an increase in electromagnetic interference (EMI) noise due to a switching frequency.

Also, the DC-AC power converting circuit, which supplies AC power by switching DC power using an electronic switch such as, for example, a semiconductor switch has a problem in that a harmonic component is generated with respect to a frequency of AC power desired to be output.

The piezoelectric transformer is an element converting voltage levels of electric energy using mechanical energy, has the following advantages over a winding-type electromagnetic transformer.

Since a piezoelectric transformer does not require coil winding, it may be reduced in size, thickness, and weight, and may enhance productivity in mass-production. Also, magnetic loss such as eddy current loss, hysteresis loss made in the winding-type transformer, does not occur in high frequency driving, and thus, high efficiency may be obtained. In addition, the piezoelectric transformer is advantageous in terms of preventing inductive disturbance since there is no stage of conversion into magnetic energy during an energy conversion process as is the case with the winding-type transformer.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, there is provided a direct current (DC)-alternating current (AC) power converting circuit for removing a harmonic component and reducing loss according to removal of the harmonic component through a simple configuration.

In another general aspect, a direct current (DC)-alternating current (AC) power converting circuit may include an inverter configured to convert the DC power into first output power, a piezoelectric transforming unit including piezoelectric transformers connected in parallel to an output terminal of the inverter, and each piezoelectric transformer of the piezoelectric transformers configured to transform the first output power to second output power, and an output configured to add the second output power output from the each of the piezoelectric transformer and to output AC power, wherein each piezoelectric transformer has a resonance frequency.

The resonance frequency of the each of the piezoelectric transformer may be a fundamental frequency or a harmonic frequency of the first output power.

The piezoelectric transformers may have different input/output transformation ratios.

The each piezoelectric transformer may include an input piezoelectric layer formed by stacking piezoelectric layers in a first direction, an output piezoelectric layer formed by stacking piezoelectric layers in a second direction, and an insulating layer configured to electrically insulate the input piezoelectric layer and the output piezoelectric layer from each other.

The input piezoelectric layer may be configured to convert the first output power to a first vibration in the first direction, and in response to the first vibration, the output piezoelectric layer may be configured to convert a second vibration, in a second direction into the second output power.

The each piezoelectric transformer may include an input piezoelectric layer formed by stacking piezoelectric layers in a first direction, an output piezoelectric layer formed by stacking piezoelectric layers in the first direction, and an insulating layer configured to electrically insulate the input piezoelectric layer and the output piezoelectric layer from each other.

The input piezoelectric layer may be configured to convert the first output power to a first vibration in the first direction, and in response to the first vibration, the output piezoelectric layer may be configured to convert a second vibration in the first into the second output power.

The inverter may be a full-bridge inverter.

The input piezoelectric layer may include a first input electrode and a second input electrode formed on two opposing surfaces of the input piezoelectric layer.

The output piezoelectric layer may include a first output electrode and a second output electrode formed on two opposing surfaces of the output piezoelectric layer.

A polarization direction of the input piezoelectric layer may be different than a polarization direction of the output piezoelectric layer.

The insulating layer may include a ductile thin film.

The insulating layer may include a hollow portion.

A direct current (DC)-alternating current (AC) power converting circuit including an inverter configured to convert the DC power into square wave power, a piezoelectric transforming unit including piezoelectric transformers connected in parallel to an output terminal of the inverter unit, and each piezoelectric transformer of the piezoelectric transformers generating first kinetic energy from the square wave power and converting second kinetic energy induced by the first kinetic energy into electric energy, and an output configured to add outputs from the piezoelectric transformers to output AC power.

The resonance frequency of each of the piezoelectric transformers may be a fundamental frequency or a harmonic frequency of the square wave power.

The piezoelectric transformers may have different input/output transformation ratios.

Other features and aspects will be apparent from the following detailed description, the drawings, and the claims.

### BRIEF DESCRIPTION OF DRAWINGS

FIG. 1 is a diagram illustrating an example of a direct current (DC)-alternating current (AC) power converting circuit;

FIG. 2 is a diagram illustrating an example of a piezoelectric transformer including a DC-AC power converting circuit.

FIG. 3 is a diagram illustrating an example of a view taken along line III-III′ of FIG. 2.

FIG. 4 is a diagram illustrating an example of a piezoelectric transformer including a DC-AC power converting circuit.

FIG. 5 is a diagram illustrating an example of a view taken along line V-V′ of FIG. 4.

FIG. 6 is a diagram illustrating an example of a DC-AC power converting circuit.

FIG. 7 is a simulation graph illustrating an example of second output powers and AC power of the DC-AC power converting circuit illustrated in FIG. 6.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the examples.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular examples only and is not intended to be limiting of the present inventive concept. As used herein, the singular forms “a,” “an,” and “the” are intended to include the plural forms as well, unless the context clearly indicates otherwise.

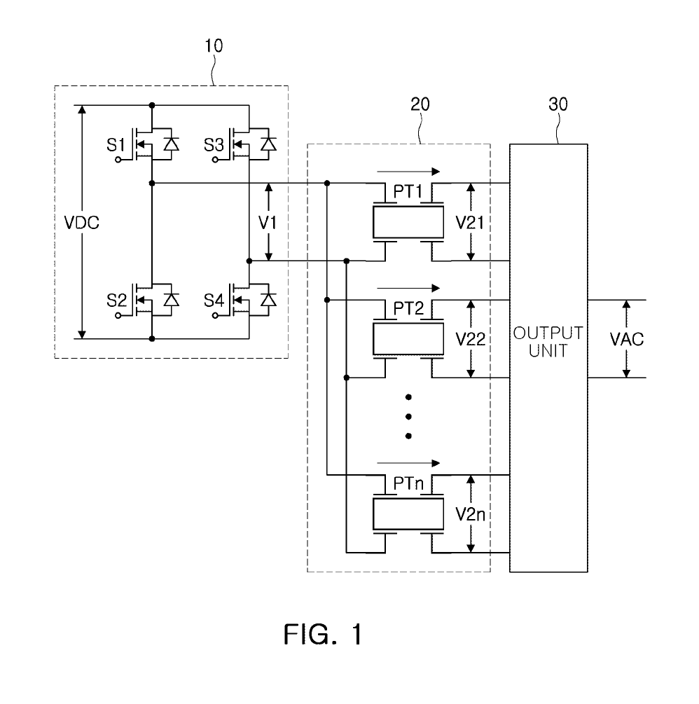

FIG. 1 is a circuit diagram illustrating an example of a direct current (DC)-alternating current (AC) power converting circuit. Referring to FIG. 1, an example of the DC-AC power converting circuit may include an inverter unit 10, a piezoelectric transforming unit 20, and an output unit 30.

The inverter unit 10 may switch DC power VDC to convert it into a first output power V1. The inverter unit 10 may comprise switches S1, S2, S3, and S4. In an example, the inverter unit 10 may be a full-bridge inverter in which, for example, a pair of switches S1 and S4 and another pair of switches S2 and S3 may alternately operate according to a control signal to form different current paths of the DC power VDC.

Thus, the first output power V1 output from the inverter unit 10 may be square wave power.

The piezoelectric transforming unit 20 may include a plurality of piezoelectric transformers PT1, PT2, . . . , PTn connected to an output terminal of the inverter unit 10 in parallel and each having a resonance frequency, and may transform the first output power V1 to output second output powers V21, V22, . . . , V2n, respectively.

Since an input terminal and an output terminal of the piezoelectric transforming unit 20 are insulated by the piezoelectric transforming unit 20, an example of the DC-AC converting circuit does not require a separate electromagnetic interference (EMI) circuit.

Also, resonance frequencies of the plurality of the piezoelectric transformers PT1, PT2, . . . , PTn may be a fundamental frequency and a harmonics frequency of the first output power V1.

Since the plurality of piezoelectric transformers PT1, PT2, . . . , PTn each have a resonance frequency, fundamental wave, and harmonic components having a frequency corresponding to the resonance frequency included in the first output power V1 output from the inverter unit 10 may be transformed and output, while other harmonic components may be removed.

The plurality of piezoelectric transformers PT1, PT2, . . . , PTn may have different input/output transformation ratios.

In an example, the plurality of piezoelectric transformers PT1, PT2, . . . , PTn may generate a first kinetic energy from the square wave power output from the inverter unit 10, and may convert a second kinetic energy induced by the first kinetic energy into electric energy.

A ratio of magnitude of the second kinetic energy to a magnitude of the first kinetic energy is a factor determining an input/output transformation ratio of the piezoelectric transforming unit 20, and conversion efficiency of converting the second kinetic energy into electric energy is also a factor determining an input/output transformation ratio of the piezoelectric transforming unit 20.

The output unit 30, which may include a circuit for merging powers, may add the second output powers V21, V22, . . . , V2n output from the plurality of piezoelectric transformers PT1, PT2, . . . , PTn and output an AC power VAC.

Thus, since a specific harmonic component included in the first output power V1 is transformed and merged with the fundamental wave component, loss due to removal of the harmonic component may be reduced.

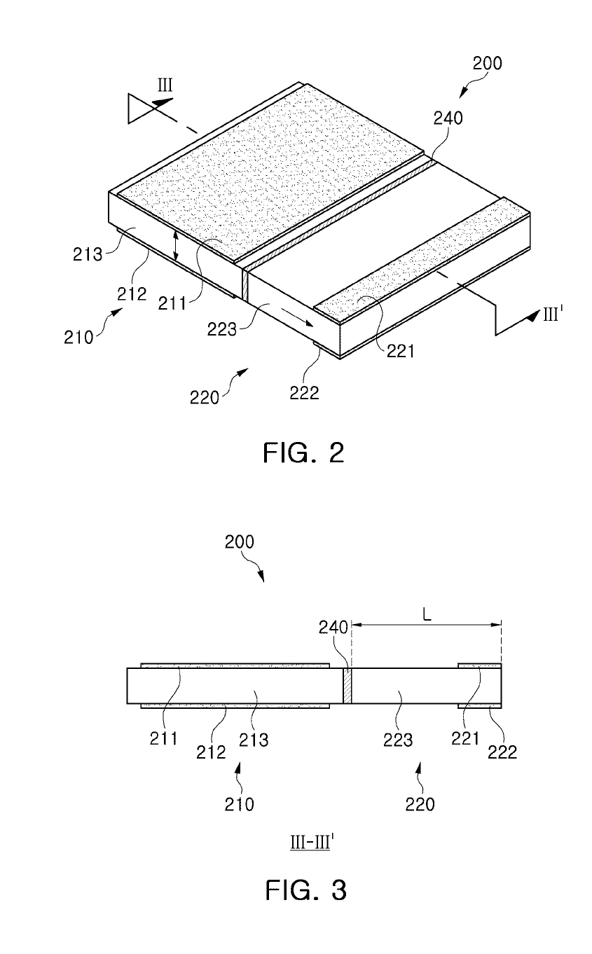

FIG. 2 is a diagram illustrating an example of a piezoelectric transformer including a DC-AC power converting circuit, and FIG. 3 is a cross-sectional view taken along line III-III′ of FIG. 2.

A configuration and operation of the piezoelectric transformer 200 according to an example will be described with reference to FIGS. 2 and 3.

The piezoelectric transformer 200, a transformer using a piezoelectric effect, includes two separate piezoelectric layers 210 and 220. According to an example, the piezoelectric transformer 200 may further include an insulating layer 240.

In the example of FIG. 2, the first piezoelectric layer 210 will be described as an input piezoelectric layer and the second piezoelectric layer 220 will be described as an output piezoelectric layer, but this is merely illustrative. In another example, the first piezoelectric layer 210 may be an output piezoelectric layer and the second piezoelectric layer 220 may be described as an input piezoelectric layer.

The input piezoelectric layer 210 may include a plurality of piezoelectric layers 213 and input electrodes 211 and 212 stacked in a first direction. The input electrodes 211 and 212 may be formed on surfaces of the input piezoelectric layer 210 to apply an input voltage.

The output piezoelectric layer 220 may include a plurality of piezoelectric layers 223 and output electrodes 221 and 222 stacked in a second direction. The output electrodes 221 and 222 may be formed on surfaces of the output piezoelectric layer 220 to output an output voltage.

Polarization directions of the input piezoelectric layer 210 and the output piezoelectric layer 220 may be different from each other. In the illustrated example, the polarization direction of the input piezoelectric layer 210 is formed in a thickness direction, and the polarization direction of the output piezoelectric layer 220 is formed in a length direction.

When input power having a resonance frequency is applied to the input piezoelectric layer 210, the input piezoelectric layer 210 may generate a first kinetic energy, and the output piezoelectric layer 220 may output electric energy using a second kinetic energy induced by the first kinetic energy from the input piezoelectric layer 210.

Since the polarization direction of the input piezoelectric layer 210 is a thickness direction, when input power is applied, the input piezoelectric layer 210 may vibrate in the thickness direction. Such vibration may be transmitted as a length-directional vibration to the adjacent output piezoelectric layer 220, and the output piezoelectric layer 220 may convert the length-directional vibration into electric energy and output the converted electric energy.

The Rosen-type piezoelectric transformer illustrated in FIG. 3 may be applied where a voltage of output power is higher than a voltage of input power, but without being limited thereto.

The insulating layer 240 is formed between the input piezoelectric layer 210 and the output piezoelectric layer 220 to electrically insulate the input piezoelectric layer 210 and the output piezoelectric layer 220 from each other.

The insulating layer 240 may be formed of various materials having insulating properties, such as, for example, a ceramic material having high insulating properties. In another example, the insulating layer 240 may be a sheet or a film formed of a resin.

In an example, a thin film having insulating properties and ductility may be used as the insulating layer 240. When the insulating layer 240 is formed of a ceramic material, fatigue is increased due to vibrations to crack or damage the insulating layer 240. Rigidity of the ceramic material may also hinder smooth transmission of vibrations of the input piezoelectric layer 210 to the output piezoelectric layer 220.

In an example, at least one hollow portion (not shown) may be formed in the insulating layer 240. Since the hollow portion is filled with air or is empty in a vacuum state, the input piezoelectric layer 210 and the output piezoelectric layer 220 may be electrically separated through the hollow portion. The insulating layer 240 having the hollow portion may be significantly reduced in actual volume, compared to a case without the hollow portion. The insulating layer 240 may minimize attenuation of vibrations of the input piezoelectric layer 210 by a minimum area, and vibrations may be effectively transmitted to the output piezoelectric layer 220.

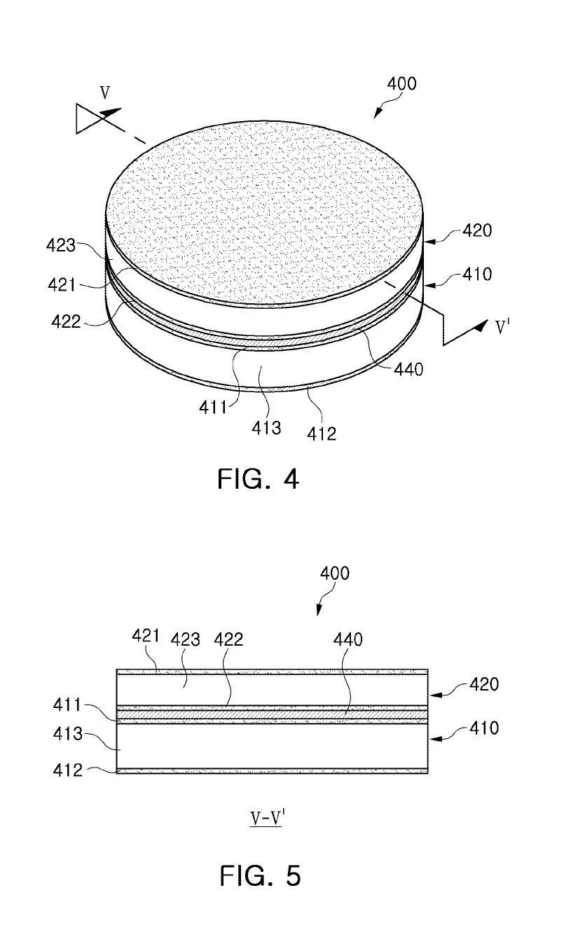

FIG. 4 is a diagram illustrating an example of a piezoelectric transformer including a DC-AC power converting circuit, and FIG. 5 is a diagram illustrating an example of a cross-sectional view taken along line V-V′ of FIG. 4.

A piezoelectric transformer 400 described hereinafter may have a configuration and operation corresponding to those of the piezoelectric transformer 200 described above with reference to FIGS. 2 and 3. The above description of FIGS. 1-3, is also applicable to piezoelectric transformer 400, and is incorporated herein by reference. Thus, the above description may not be repeated here.

Similar to the piezoelectric transformer 200 described above with reference to FIGS. 2 and 3, the piezoelectric transformer 400 may include two separate piezoelectric layers 410 and 420 and an insulating layer 440 positioned between the piezoelectric layers 410 and 420.

Unlike the example of FIGS. 2 and 3, in the piezoelectric transformer 400 according to the present example, the input piezoelectric layer 410 and the output piezoelectric layer 420 may be stacked in the same direction.

The input piezoelectric layer 410 may be formed by stacking a plurality of piezoelectric layers 413 in a height direction, and the output piezoelectric layer 420 may also be formed by stacking a plurality of piezoelectric layers 423 in the height direction. According to another example, the input piezoelectric layer 410 and the output piezoelectric layer 420 may be formed by stacking a plurality of piezoelectric layers in another direction, rather than in the height direction.

When input power having a resonance frequency is applied to the input piezoelectric layer 410, the input piezoelectric layer 410 may generate a first vibration in a vertical direction, and the output piezoelectric layer 420 may output electric energy using a vertical directional second vibration of the output piezoelectric layer 420, which is induced by the first vibration.

The radial-type piezoelectric transformer 400 illustrated in FIG. 4 may be applied to a case in which a voltage of output power is lower than a voltage of input power, but without being limited thereto. The examples of the piezoelectric transformers shown in FIGS. 2-5 are only non-exhaustive illustrations of the piezoelectric transformer, and other piezoelectric transformer are considered to be well within the scope of the present disclosure.

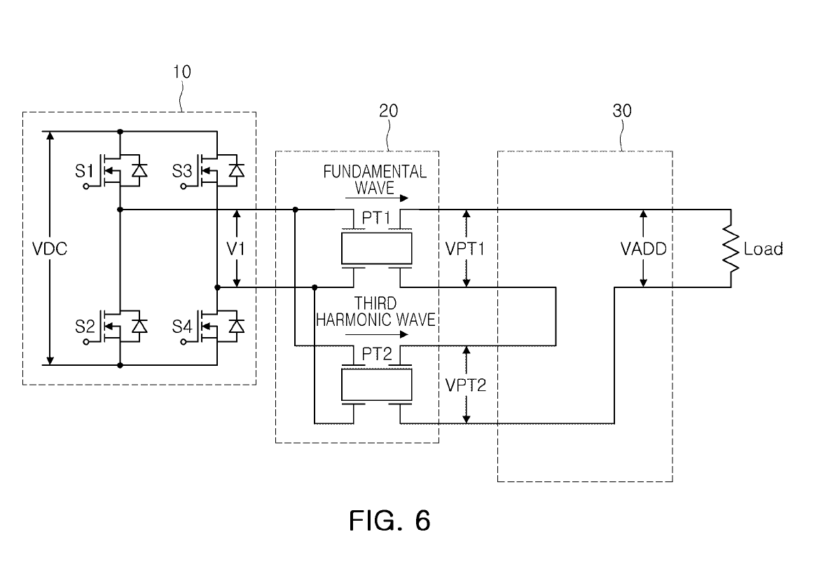

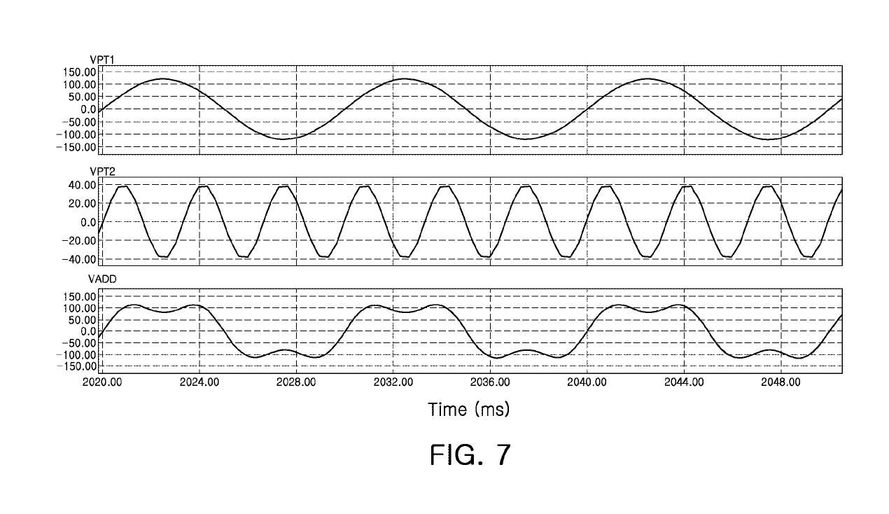

FIG. 6 is a diagram illustrating an example of a DC-AC power converting circuit, and FIG. 7 is a simulation graph illustrating an example of a second output powers and AC power of the DC-AC power converting circuit illustrated in FIG. 6.

Referring to FIG. 6, a DC-AC power converting circuit according to the present example may include an inverter unit 10, a piezoelectric transforming unit 20 having two resonance frequencies, and an output unit 30.

The inverter unit 10 may switch a DC power VDC to convert it into a first output power V1.

The piezoelectric transforming unit 20 may include two piezoelectric transformers PT1 and PT2 having resonance frequencies corresponding to a fundamental wave and a third harmonic wave, respectively. The piezoelectric transforming unit 20 may transform the first output power V1 into output second output powers VPT1 and VPT2. In an example, the third harmonic component may have a frequency triple that of the fundamental wave component.

The output unit 30 may be configured to serially connect an output from the second piezoelectric transformer PT2 to an output from the first piezoelectric transformer PT1 to merge the same, and add the second output powers VPT1 and VPT2 to output an AC power VADD.

Referring to FIG. 7, the simulation graph displays the second output power VPT1 from the first piezoelectric transformer PT1, the second output power VPT2 from the second piezoelectric transformer PT2, and the AC power VADD as the sum of the second output powers VPT1 and VPT2.

In another example, where the output unit 30 of the DC-AC power converting circuit is a rectifier circuit, the circuit may be operated as a DC-DC power converting circuit, and DC power of an input side may be supplied as output side DC power without energy loss of a harmonic component.

As set forth above, the DC-AC power converting circuit according to examples may remove a harmonic component and reduce loss due to the removal of the harmonic component by a simple configuration.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A direct current (DC)-alternating current (AC) power convertor comprising:
an inverter configured to convert the DC power into first output power;
a piezoelectric transforming unit comprising piezoelectric transformers connected in parallel to an output terminal of the inverter, and each piezoelectric transformer of the piezoelectric transformers configured to transform the first output power to second output power; and
an output configured to add the second output power output from the each of the piezoelectric transformer and to output AC power,
wherein each piezoelectric transformer has a resonance frequency.

2. The DC-AC power converting circuit of claim 1, wherein the resonance frequency of the each of the piezoelectric transformer is a fundamental frequency or a harmonic frequency of the first output power.

3. The DC-AC power converting circuit of claim 1, wherein the piezoelectric transformers have different input/output transformation ratios.

4. The DC-AC power converting circuit of claim 1, wherein the each piezoelectric transformer comprises:
an input piezoelectric layer formed by stacking piezoelectric layers in a first direction;
an output piezoelectric layer formed by stacking piezoelectric layers in a second direction; and
an insulating layer configured to electrically insulate the input piezoelectric layer and the output piezoelectric layer from each other.

5. The DC-AC power converting circuit of claim 4, wherein the input piezoelectric layer is configured to convert the first output power to a first vibration in the first direction, and in response to the first vibration, the output piezoelectric layer is configured to convert a second vibration, in a second direction into the second output power.

6. The DC-AC power converting circuit of claim 1, wherein the each piezoelectric transformer comprises:
an input piezoelectric layer formed by stacking piezoelectric layers in a first direction;
an output piezoelectric layer formed by stacking piezoelectric layers in the first direction; and
an insulating layer configured to electrically insulate the input piezoelectric layer and the output piezoelectric layer from each other.

7. The DC-AC power converting circuit of claim 6, wherein the input piezoelectric layer is configured to convert the first output power to a first vibration in the first direction, and in response to the first vibration, the output piezoelectric layer is configured to convert a second vibration in the first into the second output power.

8. The DC-AC power converting circuit of claim 1, wherein the inverter is a full-bridge inverter.

9. The DC-AC power converting circuit of claim 4, wherein the input piezoelectric layer further comprises a first input electrode and a second input electrode formed on two opposing surfaces of the input piezoelectric layer.

10. The DC-AC power converting circuit of claim 4, wherein the output piezoelectric layer further comprises a first output electrode and a second output electrode formed on two opposing surfaces of the output piezoelectric layer.

11. The DC-AC power converting circuit of claim 4, wherein a polarization direction of the input piezoelectric layer is different than a polarization direction of the output piezoelectric layer.

12. The DC-AC power converting circuit of claim 4, wherein the insulating layer comprises a ductile thin film.

13. The DC-AC power converting circuit of claim 4, wherein the insulating layer comprises a hollow portion.

14. A direct current (DC)-alternating current (AC) power converting circuit comprising:
an inverter configured to convert the DC power into square wave power;
a piezoelectric transforming unit comprising piezoelectric transformers connected in parallel to an output terminal of the inverter unit, and each piezoelectric transformer of the piezoelectric transformers generating first kinetic energy from the square wave power and converting second kinetic energy induced by the first kinetic energy into electric energy; and
an output configured to add outputs from the piezoelectric transformers to output AC power.

15. The DC-AC power converting circuit of claim 14, wherein resonance frequency of each of the piezoelectric transformers is a fundamental frequency or a harmonic frequency of the square wave power.

16. The DC-AC power converting circuit of claim 14, wherein the piezoelectric transformers have different input/output transformation ratios.
